(19) United States
(12) Patent Application Publication
(10) Pub. No.: US 2026/0173724 A1
(43) Pub. Date: Jun. 18, 2026

(54) DISPLAY DEVICE

(71) Applicant: LG Display Co., Ltd., Seoul (KR)

(72) Inventors: Seungpyo HONG, Paju-si (KR); YunHo KOOK, Paju-si (KR); Jonghan PARK, Paju-si (KR); Jihyang YOON, Paju-si (KR)

(73) Assignee: LG Display Co., Ltd., Seoul (KR)

(21) Appl. No.: 19/344,866

(22) Filed: Sep. 30, 2025

(30) Foreign Application Priority Data
Dec. 13, 2024 (KR) 10-2024-0185802

(51) Int. Cl. H10K 59/80; H10K 59/122; H10K 59/35; H10K 59/38; H10K 59/65

(52) U.S. Cl. CPC H10K 59/873; H10K 59/122; H10K 59/352; H10K 59/353; H10K 59/38; H10K 59/65; H10K 59/8792

(57) ABSTRACT

A display device is discussed, which is capable of improving luminance in an optical area. The display device includes a plurality of dams surrounding a pixel electrode corresponding to an emission area located in the optical area, and an organic encapsulation layer located in an inner space surrounded by each of the plurality of dams.

### CROSS-REFERENCE TO RELATED APPLICATION

This application claims priority to Korean Patent Application No. 10-2024-0185802, filed in the Republic of Korea on Dec. 13, 2024, which is hereby expressly incorporated by reference for all purposes as if fully set forth herein.

### BACKGROUND

### Field

Embodiments of the present disclosure relate to a display device.

### Discussion of the Related Art

As the information society develops, the demand for display devices for displaying images is increasing in various forms. Recently, various display devices such as liquid crystal displays and organic light-emitting display devices are being utilized.

In addition, the display device can provide a detection function to perform a function according to the light in the surrounding environment. For this purpose, the display device can be equipped with various electronic devices (e.g., optical electronic devices) such as a detection sensor and an image sensor (e.g., a camera).

Since an electronic device needs to receive light from the front of the display device, there can be disposed a transmission area in which a cathode hole is formed in an area of a cathode electrode where the electronic device is placed.

Since the transmission area replaces an emission area of a light emitting device, there can occur a luminance differences between an area where the electronic devices is disposed and an area where the electronic devices is not disposed.

### SUMMARY OF THE DISCLOSURE

Embodiments of the present disclosure provide a display device capable of encapsulating each emission area with an organic encapsulation layer using a dam.

Embodiments of the present disclosure provide a display device capable of increasing luminance through a dome-shaped encapsulation layer.

Embodiments of the present disclosure provide a display device capable of increasing luminance through a pixel electrode including an inclined surface.

Embodiments of the present disclosure provide a display device capable of outputting high brightness with low power through a pixel electrode including a dome-shaped encapsulation layer and an inclined surface.

Embodiments of the present disclosure provide a display device capable of further increasing the transmittance of a transmission area by arranging the organic encapsulation layer so as not to overlap with the transmission area.

Embodiments of the present disclosure provide a display device capable of further increasing the transmittance of a transmission area by disposing a planarization layer in a transmission area thinner than a planarization layer disposed in an emission area, or by not disposing the planarization layer.

The tasks of the embodiments of the present disclosure are not limited to the tasks mentioned in this disclosure, and other tasks not mentioned will be clearly understood by those skilled in the art from the description below.

Embodiments of the present disclosure provide a display device including a substrate including a display area with a normal area and an optical area capable of transmitting light, the normal area including a plurality of first emission areas, the optical area including a plurality of transmission areas and a plurality of non-transmission areas, and the plurality of non-transmission areas including a plurality of second emission areas, a plurality of pixel electrodes disposed on the substrate so as to overlap with each of the plurality of first emission areas and the plurality of second emission areas, a plurality of emission layers disposed on each of the plurality of pixel electrodes, a common electrode disposed on the plurality of emission layers, a plurality of dams located in the optical area, and an organic encapsulation layer disposed on the common electrode and located in an inner space surrounded by each of the plurality of dams, wherein each of the plurality of dams surrounds at least one pixel electrode corresponding to at least one second emission area among the plurality of second emission areas.

Embodiments of the present disclosure provide a display device including a substrate including a display area with a normal area and an optical area capable of transmitting light, the normal area including a plurality of first emission areas, and the optical area including a plurality of transmission areas and a plurality of second emission areas, a plurality of first light emitting devices located in each of the plurality of first emission areas, a plurality of second light emitting devices located in each of the plurality of second emission areas, and an organic encapsulation layer disposed throughout the normal area and disposed in the plurality of second emission areas within the optical area, wherein the organic encapsulation layer is separately disposed on each of at least one of the plurality of second light emitting devices and has a dome shape.

According to embodiments of the present disclosure, it is possible to provide a display device capable of encapsulating each emission area with an organic encapsulation layer using a dam.

According to embodiments of the present disclosure, it is possible to provide a display device capable of increasing luminance through a dome-shaped encapsulation layer.

According to embodiments of the present disclosure, it is possible to provide a display device capable of increasing luminance through a pixel electrode including an inclined surface.

According to embodiments of the present disclosure, it is possible to provide a display device capable of further increasing the transmittance of a transmission area by arranging the organic encapsulation layer so as not to overlap with the transmission area.

According to embodiments of the present disclosure, it is possible to provide a display device capable of further increasing the transmittance of a transmission area by disposing a planarization layer in a transmission area thinner than a planarization layer disposed in an emission area, or by not disposing the planarization layer.

According to embodiments of the present disclosure, it is possible to provide a display device capable of outputting high brightness with low power through a pixel electrode including a dome-shaped encapsulation layer and an inclined surface.

The effects of the embodiments of the present disclosure are not limited to the effects mentioned in this disclosure, and other effects not mentioned will be clearly understood by those skilled in the art from the description of the claims.

### BRIEF DESCRIPTION OF THE DRAWINGS

The present disclosure will be more fully understood from the detailed description and accompanying drawings provided below, which are provided for illustration only and are not intended to limit the present disclosure.

FIG. 1 illustrates a display device according to embodiments of the present disclosure.

FIG. 2 illustrates a system configuration diagram of a display device according to embodiments of the present disclosure.

FIG. 3 illustrates a display panel according to embodiments of the present disclosure.

FIG. 4 illustrates a layout of sub-pixels in two areas included in the display area of the display panel according to embodiments of the present disclosure.

FIG. 5 is a plan view of the area A shown in FIG. 4 according to embodiments of the present disclosure, and an enlarged view of a portion of the plan view of the area A.

FIG. 6 is a cross-sectional view of the display panel along the dotted line B-B′ shown in FIG. 5.

FIG. 7 is a plan view of the area A shown in FIG. 4 according to embodiments of the present disclosure, and an enlarged view of a portion of the plan view of the area A.

FIG. 8 is a cross-sectional view of the display panel along the dotted line C-C′ shown in FIG. 7.

FIG. 9 is a plan view of the area A shown in FIG. 4 according to embodiments of the present disclosure, and an enlarged view of a portion of the plan view of the area A.

FIG. 10 is a cross-sectional view of the display panel along the dotted line D-D′ shown in FIG. 9.

FIG. 11 is a plan view of the area A shown in FIG. 4 according to embodiments of the present disclosure, and an enlarged view of a portion of the plan view of the area A.

FIG. 12 is a cross-sectional view of the display panel along the dotted line E-E′ shown in FIG. 11.

FIG. 13 is a plan view of the area A shown in FIG. 4 according to embodiments of the present disclosure, and an enlarged view of a part of the plan view of area A.

FIG. 14 is a cross-sectional view of a display panel along the F-F′ dotted line shown in FIG. 13.

### DETAILED DESCRIPTION OF THE EMBODIMENTS

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description can make the subject matter in some embodiments of the present invention rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B),” can be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

Hereinafter, various embodiments of the disclosure are described in detail with reference to the accompanying drawings. All the components of each display device/apparatus according to all embodiments of the present disclosure are operatively coupled and configured.

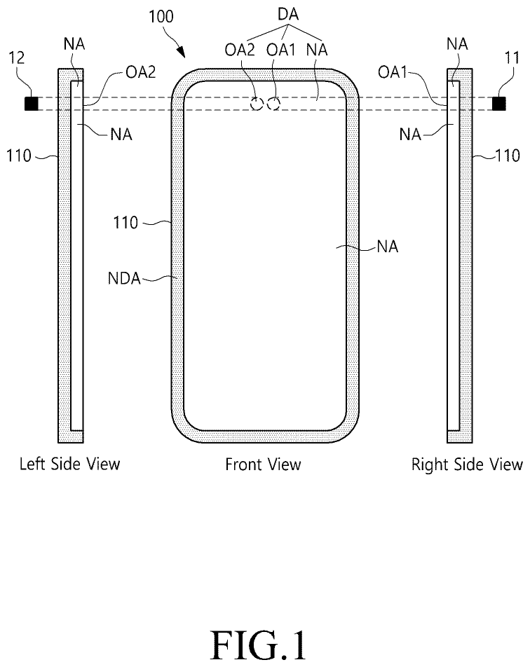

FIG. 1 illustrates a display device 100 according to embodiments of the present disclosure.

Referring to FIG. 1, the display device 100 according to embodiments of the present disclosure can include a display panel 110 for displaying an image and one or more optical electronic devices 11 and 12.

The display panel 110 can include a display area DA where an image is displayed and a non-display area NDA where an image is not displayed.

There can be disposed a plurality of sub-pixels and a plurality of signal lines for driving the plurality of sub-pixels in the display area DA.

The non-display area NDA can be an area outside the display area DA. Various signal lines can be disposed in the non-display area NDA, and various driving circuits can be connected thereto. The non-display area NDA can be bent so that it is not visible from the front or can be obscured by a case. The non-display area NDA can be also referred as a bezel or a bezel area.

Referring to FIG. 1, in a display device 100 according to embodiments of the present disclosure, one or more optical electronic devices 11 and 12 can be provided and installed separately from the display panel 110, and can be an electronic component located at the lower part of the display panel 110 (i.e., opposite the viewing surface).

The light can enter the front (i.e., viewing side) of the display panel 110, pass through the display panel 110, and can be delivered to one or more optical electronic devices 11 and 12 located below the display panel 110 (i.e., opposite the viewing surface). For example, light passing through the display panel 110 can include visible light, infrared light, or ultraviolet light..

One or more optical electronic devices 11 and 12 can be devices which receive light passing through the display panel 110 and perform a predetermined function using the received light. For example, the one or more optical electronic devices 11 and 12 can include one or more of a photographing device such as a camera (i.e., image sensor), a detection sensor such as a proximity sensor, and an illuminance sensor. Here, for example, the detection sensor can be an infrared sensor.

In the display device 100 according to embodiments of the present disclosure, the display area DA can include a normal area NA and one or more optical areas OA1 and OA2. One or more optical areas OA1 and OA2 can be areas which overlap with one or more optical electronic devices 11 and 12.

According to the example of FIG. 1, the display area DA can include the normal area NA, a first optical area OA1, and a second optical area OA2. In the example of FIG. 1, the normal area NA can exist between the first optical area OA1 and the second optical area OA2. Here, at least a portion of the first optical area OA1 can overlap with a first optical electronic device 11, and at least a portion of the second optical area OA2 can overlap with a second optical electronic device 12.

One or more optical areas OA1 and OA2 are required to or can include both an image display structure and a light transmission structure. For example, since one or more optical areas OA1 and OA2 are part of the display area DA, emission areas of sub-pixels for image display are needed to be disposed in the one or more optical areas OA1 and OA2. Additionally, a light transmission structure is needed to be formed in one or more optical areas OA1 and OA2 to transmit light to one or more optical electronic devices 11 and 12.

One or more optical electronic devices 11 and 12 are devices that use or need optical reception, and can be located behind (i.e., below or opposite to the viewing surface) the display panel 110 and receive light passing through the display panel 110. One or more optical electronic devices 11 and 12 can be not exposed to the front (i.e., viewing side) of the display panel 110. Accordingly, when the user looks at the front of the display device 110, the optical electronic devices 11 and 12 can be not visible to the user.

For example, a first optical electronic device 11 can be a camera, and a second optical electronic device 12 can be a detection sensor such as a proximity sensor or illuminance sensor. For example, the detection sensor can be an infrared sensor for detecting infrared rays. Alternatively, the first optical electronic device 11 can be a detection sensor, and the second optical electronic device 12 can be a camera.

Hereinafter, for convenience of explanation, there is exemplified a case in which the first optical electronic device 11 is a camera and the second optical electronic device 12 is an infrared-based detection sensor. Here, the camera can be a camera lens or an image sensor.

In the case that the first optical electronic device 11 is a camera, the camera can be located behind (i.e., below) the display panel 110, but can be a front camera for photographing the front direction of the display panel 110. Accordingly, the user can view a viewing surface of the display panel 110 and take pictures or self-photographs using a camera which is not visible to the viewing surface.

The normal area NA and one or more optical areas OA1 and OA2 can be areas capable of displaying an image. However, the normal area NA can be an area in which a light transmission structure does not need to be formed, and one or more optical areas OA1 and OA2 can be areas in which a light transmission structure is needed to be formed.

Therefore, one or more optical areas OA1 and OA2 are needed to have transmittance above a specific level, and the normal area NA may not have light transmittance or can have low transmittance below a specific level.

For example, the number of sub-pixels per unit area in one or more optical areas OA1 and OA2 can be smaller than the number of sub-pixels per unit area in the normal area NA. For example, the resolution of one or more optical areas OA1 and OA2 can be lower than the resolution of the normal area NA. Here, the number of sub-pixels per unit area can mean the same as resolution, pixel density, or pixel integration. For example, a unit of the number of sub-pixels per unit area can be PPI (Pixels Per Inch), which means the number of pixels in 1 inch.

For example, the number of sub-pixels per unit area in the first optical area OA1 can be less than the number of sub-pixels per unit area in the normal area NA. The number of sub-pixels per unit area in the second optical area OA2 can be greater than or equal to the number of sub-pixels per unit area in the first optical area OA1, and can be less than the number of sub-pixels per unit area in the normal area NA.

Meanwhile, as a method to increase the transmittance of at least one of the first optical area OA1 and the second optical area OA2, there can be applied a differential pixel density design method, as described above. According to the differential pixel density design method, the display panel 110 can be designed so as for the number of sub-pixels per unit area of at least one of the first optical area OA1 and the second optical area OA2 to be less than the number of sub-pixels per unit area of the normal area NA.

Hereinafter, for convenience of explanation, it is assumed that the differential pixel density design method is applied as a method for increasing the transmittance of at least one of the first optical area OA1 and the second optical area OA2. Accordingly, in the following, a smaller number of sub-pixels per unit area can correspond to a smaller sub-pixel size, and a larger number of sub-pixels per unit area can correspond to a larger sub-pixel size.

The first optical area OA1 can have various shapes such as circular, oval, square, hexagon, or octagon. The second optical area OA2 can have various shapes, such as circular, oval, square, hexagon, or octagon. The first optical area OA1 and the second optical area OA2 can have the same shape or different shapes.

Hereinafter, for convenience of explanation, as an example, a case in which each of the first optical area OA1 and the second optical area OA2 has circular shape is discussed.

In the display device 100 according to the embodiments of the present disclosure, if the first optical electronic device 11, which is not exposed to the outside and is hidden at the bottom of the display panel 100, is a camera, a display device 100 according to embodiments of the present disclosure can be referred as a display device to which UDC (Under Display Camera) technology is applied.

Accordingly, in the display device 100 according to embodiments of the present disclosure, there may not be needed to be formed a notch or camera hole for camera exposure in the display panel 110, so that there is no reduction in area of the display area DA. Accordingly, the size of the bezel area can be reduced, design restrictions can be eliminated, and the degree of freedom in design can be increased.

In the display device 100 according to embodiments of the present disclosure, although the one or more optical electronic devices 11 and 12 are hidden behind the display panel 110, the one or more optical electronic devices 11 and 12 are needed to be able to receive light normally and normally perform a designated function thereof.

In addition, in the display device 100 according to embodiments of the present disclosure, although the one or more optical electronic devices 11 and 12 are hidden behind the display panel 110 and are located overlapping with the display area DA, the normal image display function is possible in one or more optical areas OA1 and OA2 overlapping with one or more optical electronic devices 11 and 12 in the display area DA.

Since the first optical area OA1 is designed as an area capable of transmitting light, the image display characteristics in the first optical area OA1 can be different from the image display characteristics in the normal area NA.

Hereinafter, for convenience of explanation, it is assumed that the display device 100 according to the embodiments of the present disclosure includes only one optical area OA among the two optical areas OA1 and OA2. For example, it is assumed that the display device 100 according to the embodiments of the present disclosure has one optical area OA. However, this is only an assumption for convenience of explanation, and the embodiments of the present disclosure are not limited thereto.

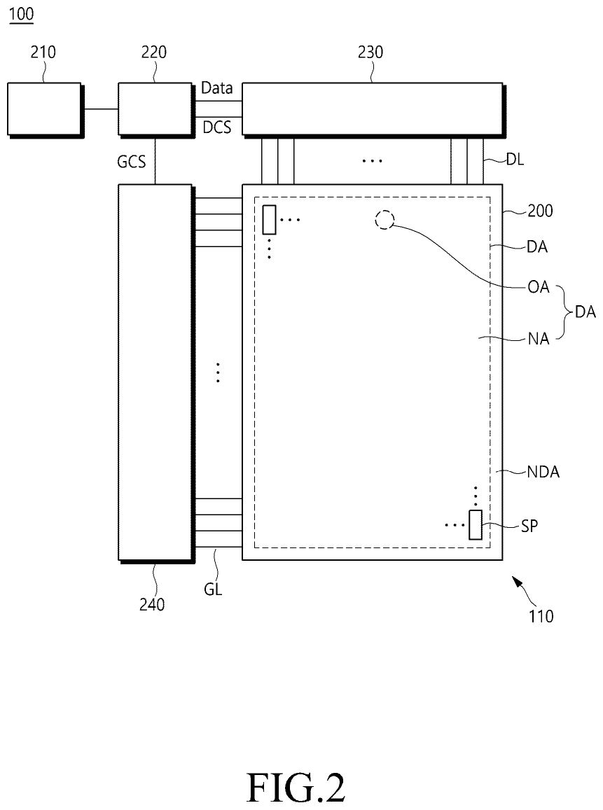

FIG. 2 illustrates a system configuration diagram of a display device 100 according to embodiments of the present disclosure.

Referring to FIG. 2, the display device 100 can include a display panel 110 and a display driving circuit as components for displaying an image.

The display driving circuit can be a circuit for driving the display panel 110, and can include a data driving circuit 230, a gate driving circuit 240 and a display controller 220.

The display panel 110 can include a display area DA for displaying an image and a non-display area NDA where an image is not displayed. The non-display area NDA can be an area outside the display area DA, and can also be referred to as a bezel area. All or part of the non-display area NDA can be an area visible from the front of the display device 100, or can be an area which is bent and not visible from the front of the display device 100.

The display panel 110 can include a substrate 200 and a plurality of sub-pixels SP disposed on the substrate 20. Additionally, the display panel 110 can further include various types of signal lines to drive the plurality of sub-pixels SP.

The display device 100 according to embodiments of the present disclosure can be a self-luminous display device in which the display panel 110 emits light on its own. However, the display device 100 according to the embodiments of the present disclosure is not limited to a self-luminous display device.

The plurality of data lines DL and the plurality of gate lines GL can cross each other. Each of the plurality of data lines DL can be arranged to extend in a first direction. Each of the plurality of gate lines GL can be arranged to extend in a second direction. Here, the first direction can be a column direction and the second direction can be a row direction. Alternatively, the first direction can be a row direction and the second direction can be a column direction.

The data driving circuit 230 is a circuit for driving a plurality of data lines DL, and can output data signals to the plurality of data lines DL. The gate driving circuit 240 is a circuit for driving a plurality of gate lines GL, and can output gate signals to the plurality of gate lines GL.

The display controller 220 can be a device for controlling the data driving circuit 230 and the gate driving circuit 240 depending on the timing implemented in each frame, and can control the driving timing for the plurality of data lines DL and the driving timing of the plurality of gate lines GL.

The display controller 220 can supply a data driving control signal DCS to the data driving circuit 230 to control the data driving circuit 220, and can supply a gate driving control signal GCS to the gate driving circuit 240 to control the gate driving circuit 230.

The display controller 220 can receive input image data from a host system 210 and supply image data to the data driving circuit 230 based on the input image data.

The data driving circuit 230 can receive image data in digital form from the display controller 240 and convert the received image data into analog data signals to output to a plurality of data lines DL.

The gate driving circuit 240 can receive a first gate voltage corresponding to the turn-on level voltage and a second gate voltage corresponding to the turn-off level voltage along with various gate driving control signals GCS, and can generate gate signals and supply the generated gate signals to the plurality of gate lines GL.

The display device 100 can further include a power supply circuit that supplies various types of power to the display driving circuit.

The display device 100 according to the embodiments of the present disclosure can be a mobile terminal such as a smart phone or tablet, or a monitor or television (TV) of various sizes, and is not limited thereto, and can be a display of various types and sizes capable of displaying information or images.

As described above, the display area DA in the display panel 110 can include a normal area NA and an optical area OA. The normal area NA and the optical area OA can be areas capable of displaying images. However, the normal area NA is an area where a light-transmitting structure does not need to be formed, and the optical area OA is an area where a light-transmitting structure is needed to be formed.

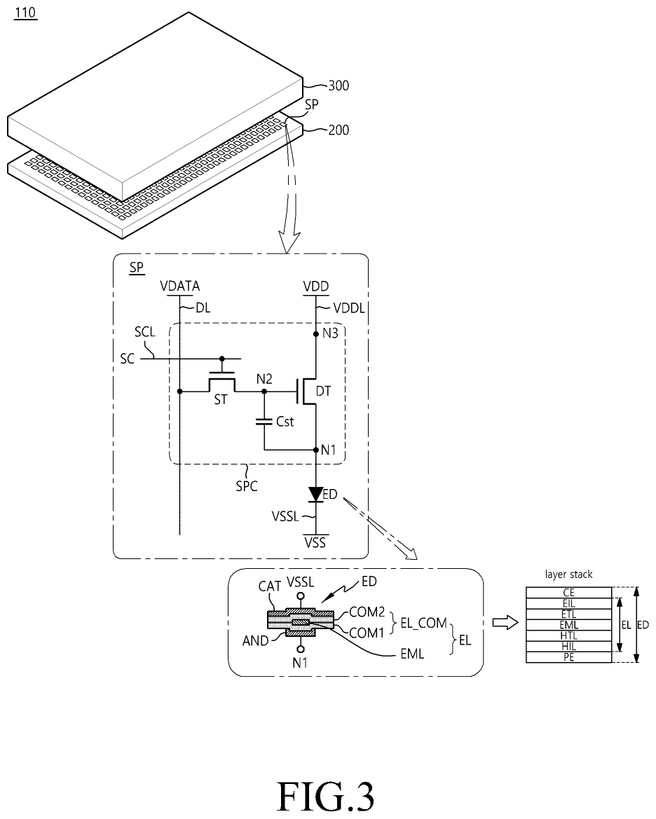

FIG. 3 illustrates a display panel 110 according to embodiments of the present disclosure.

Referring to FIG. 3, a plurality of sub-pixels SP can be disposed in the display area DA of the display panel 110. The plurality of sub-pixels SP can be disposed in the normal area NA and the optical area OA included in the display area DA.

Each of the plurality of sub-pixels SP can include a light emitting device ED and a sub-pixel circuit SPC configured to drive the light emitting device ED.

The sub-pixel circuit SPC can include a driving transistor DT that supplies a driving current Id for driving the light emitting device ED, a scan transistor ST for transferring the data voltage VDATA to the driving transistor DT, and a storage capacitor Cst for maintaining a constant voltage during one frame.

The driving transistor DT can include a first node N1, a second node N2, and a third node N3. The first node N1 can be a node which is electrically connected to the light emitting device ED. The second node N2 can be a node which is connected to the scan transistor ST. The third node N3 can be a node which is connected to a driving voltage line VDDL. The first node N1 can be electrically connected to the pixel electrode PE of the light emitting device ED. The data voltage VDATA can be applied to the second node N2. A driving voltage VDD can be applied to the third node N3. The first node N1 can be a source node or a drain node, the second node N2 can be a gate node, and the third node N3 can be a drain node or a source node. Hereinafter, for convenience of explanation, in the driving transistor DT, it will be exemplified a case in which the first node N1 is a source node, the second node N2 is a gate node, and the third node N3 is a drain node.

The light emitting device ED can include a pixel electrode PE, an intermediate layer EL, and a common electrode CE. The pixel electrode PE can be an electrode disposed in each sub-pixel SP. For example, the pixel electrode PE can be electrically connected directly or indirectly (via another transistor) to the first node N1 of the driving transistor DT of each sub-pixel SP. The common electrode CE can be an electrode commonly disposed in the plurality of sub-pixels SP. For example, the common electrode CE can be electrically connected to a base voltage line VSSL. A base voltage VSS, which is a type of common driving voltage, can be applied to the common electrode CE through the base voltage line VSSL. For example, the pixel electrode PE can be an anode electrode, and the common electrode CE can be a cathode electrode. Alternatively, the pixel electrode PE can be a cathode electrode, and the common electrode CE can be an anode electrode. Hereinafter, for convenience of explanation, it is assumed that the pixel electrode PE is an anode electrode and the common electrode CE is a cathode electrode.

The intermediate layer EL can include an emission layer EML and a common intermediate layer EL_COM.

The emission layer EML can be disposed in an emission area of each of the plurality of sub-pixels SP. For example, the emission layer EML can be disposed only in each of the plurality of sub-pixels SP. As another example, the emission layer EML can be commonly disposed in a plurality of sub-pixels SP. As another example, the emission layer EML can be disposed only in the emission area. As another example, the emission layer EML can be disposed in both the emission area and a non-emission area.

The common intermediate layer EL_COM can be commonly disposed across a plurality of sub-pixels SP. The common intermediate layer EL_COM can be commonly disposed over a plurality of emission areas EA and non-emission areas.

The common intermediate layer EL_COM can include a first common intermediate layer COM1 and a second common intermediate layer COM2. The first common intermediate layer COM1 can be disposed between the pixel electrode PE and the emission layer EML, and can include at least one layer (e.g., an organic layer). The second common intermediate layer COM2 can be disposed between the emission layer EML and the common electrode CE, and can include at least one layer (e.g., an organic layer).

For example, the first common intermediate layer COM1 can include a hole injection layer HIL and a hole transfer layer HTL. The second common intermediate layer COM2 can include an electron transport layer ETL, an electron injection layer EIL, and the like. The hole injection layer can inject holes from the pixel electrode PE to the hole transport layer, the hole transport layer can transport holes to the emission layer EML, and the electron injection layer can inject electrons from the common electrode CE to the electron transport layer, and the electron transport layer can transport electrons to the emission layer EML. However, in addition to the hole injection layer HIL, hole transport layer HTL, electron injection layer EIL, and electron transport layer ETL described above, other layers can be further arranged in the first common intermediate layer COM1 and the second common intermediate layer COM2. This can follow the OLED device structure that is typically developed.

Each light emitting device ED can include an overlapping portion of a pixel electrode PE, an emission layer EML in the intermediate layer EL, and a common electrode CE. A predetermined emission area EA can be formed by each light emitting device ED. For example, the emission area EA can be defined as an area where the pixel electrode PE, the emission layer EML in the intermediate layer EL, and the common electrode CE overlap. For example, the light emitting device ED can be an organic light emitting diode (OLED) based on organic materials, an inorganic light emitting diode based on inorganic materials, or a quantum dot light emitting device. In the case that the light emitting device ED is an organic light emitting diode, the intermediate layer EL in the light emitting device ED can include an organic layer containing an organic material.

The scan transistor ST can be controlled on-off by a scan signal SC as a type of gate signal applied through the scan signal line SCL as a type of gate line GL, and can be electrically connected between the second node N2 of the driving transistor DT and the data line DL.

The storage capacitor Cst can be electrically connected between the first node N1 and the second node N2 of the driving transistor DT.

The sub-pixel circuit SPC can have a 2T(Transistor)-1C (Capacitor) structure including two transistors DT and ST and one capacitor Cst, as shown in FIG. 3, and can further include one or more transistors or one or more capacitors in some case.

The storage capacitor Cst can be an external capacitor intentionally designed outside the driving transistor DT rather than a parasitic capacitor (e.g., Cgs, Cgd) as an internal capacitor which can exist between the first node N1 and the second node N2 of the driving transistor DT. Each of the driving transistor DT and the scan transistor ST can be an n-type transistor or a p-type transistor.

The circuit elements within each sub-pixel SP (in particular, light emitting devices EDs implemented with organic light emitting diodes (OLEDs) containing organic materials) can be vulnerable to external moisture or oxygen. Therefore, there can be disposed an encapsulation layer 300 on the display panel 110 to prevent oxygen from penetrating into the circuit elements (particularly, the light emitting device ED). The encapsulation layer 300 can be disposed to cover the light emitting devices ED.

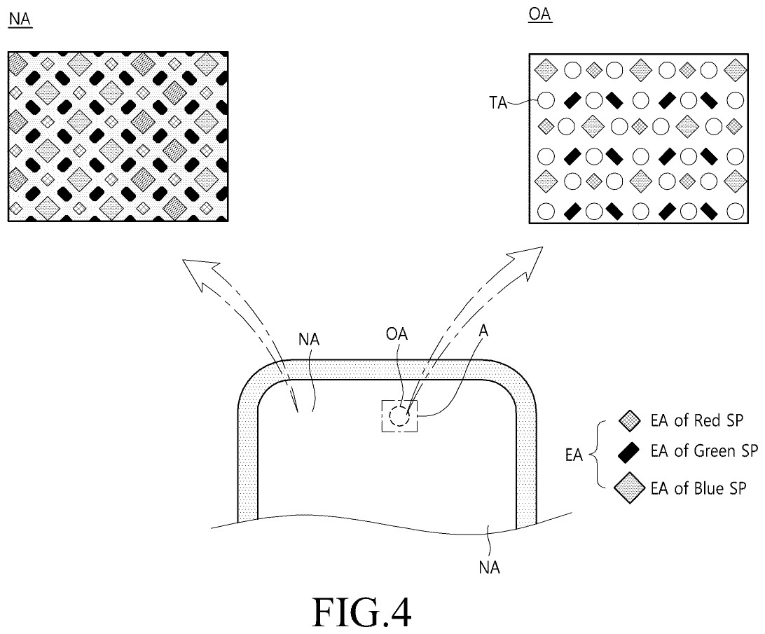

FIG. 4 illustrates, as an example, a layout of sub-pixels SP in two areas NA and OA included in the display area DA of the display panel 110 according to embodiments of the present disclosure.

Referring to FIG. 4, a plurality of sub-pixels SP can be arranged in each of the normal area NA and the optical area OA included in the display area DA of the display panel 110.

For example, the plurality of sub-pixels SP can include a red sub-pixel (Red SP) that emits red light, a green sub-pixel (Green SP) that emits green light, and a blue sub-pixel (Blue SP) that emits blue light.

Accordingly, each of the normal area NA and the optical area OA can include an emission area EA of a red sub-pixel (Red SP), an emission area EA of a green sub-pixel (Green SP), and an emission area EA of a blue sub-pixel (Blue SP).

The normal area NA may not include a light-transmitting structure, but can include emission areas EA.

However, the optical area OA is needed to include not only emission areas EA, but also a light-transmitting structure.

Therefore, the optical area OA can include emission areas EA and a transmission area TA.

The emission areas EA and the transmission area TA can be distinguished depending on whether light is transmitted. For example, the emission areas EA can be areas that are not light-transmittable, and the transmission area TA can be areas that are light-transmittable.

In addition, the emission areas EA and the transmission area TA can be distinguished depending on whether a specific metal layer CE is formed. For example, a common electrode CE can be formed in the emission areas EA, and a common electrode CE may not be formed in the transmission area TA. A light shield layer can be formed in the emission areas EA, and a light shield layer may not be formed in the transmission area TA.

Since the optical area OA includes the transmission area TA, the optical area OA can be an area through which light can be transmitted.

In addition, in the embodiments of the present disclosure, the transmission area TA can also be referred to as a transparent area, and a transmittance can also be referred to as a transparency.

Further, in the embodiments of the present disclosure, it is assumed that the optical area OA is located at the top of the display area DA of the display panel 110.

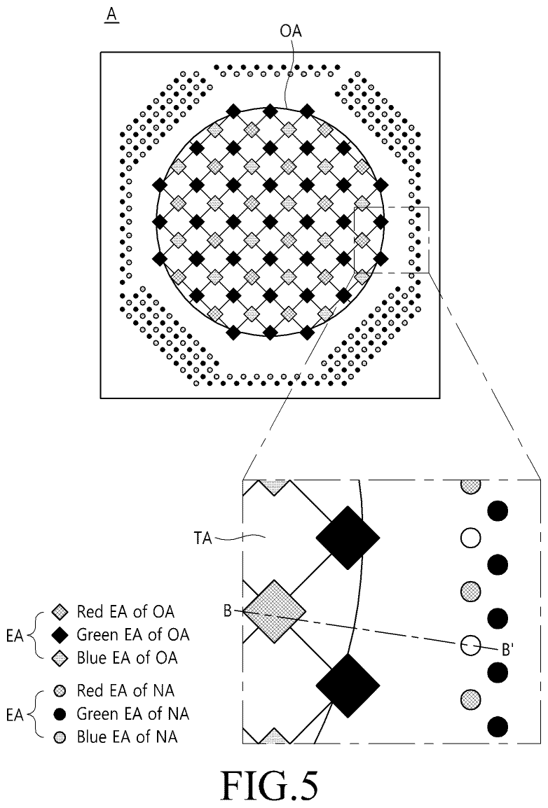

FIG. 5 is a plan view of the area A shown in FIG. 4 according to embodiments of the present disclosure, and an enlarged view of a portion of the plan view of the area A.

The A area shown in FIG. 5 can include an optical area OA and a part of a normal area NA surrounding the optical area OA.

As described in FIG. 4, the normal area NA may not include a light-transmitting structure, but can include emission areas EA. The optical area OA can include not only emission areas EA but also a transmission area TA.

A red emission area (Red EA of OA) of the optical area, a green emission area (Green EA of OA) of the optical area, a blue emission area (Blue EA of OA) of the optical area, a red emission area (Red EA of NA) of the normal area, a green emission area (Green EA of NA) of the normal area, and a blue emission area (Blue EA of NA) of the normal area shown in FIG. 5 can be the same as the emission areas for each color (e.g., EA of Red SP, EA of Green SP, EA of Blue SP) shown in FIG. 4. In FIG. 5, for convenience of explanation, the emission areas EA disposed in the normal area NA and the optical area OA are simplified and illustrated.

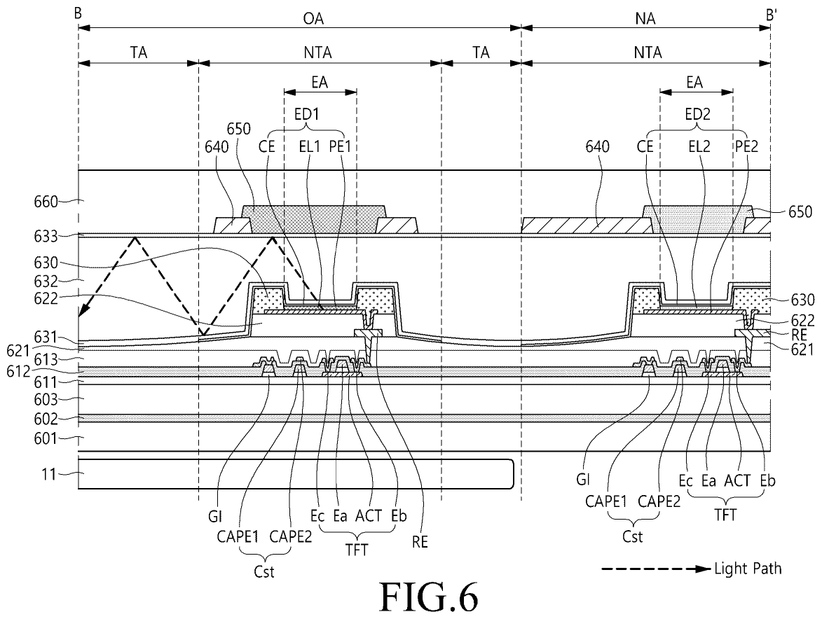

FIG. 6 is a cross-sectional view of the display panel 110 along the B-B′ dotted line shown in FIG. 5.

Referring to FIG. 6, a display panel 110 according to the embodiments of the present disclosure can include a substrate 200, a transistor section, a light emitting device section, and an encapsulation section, but the embodiments of the present disclosure are not limited thereto.

The substrate 200 can be a single layer or a multilayer. If the substrate 200 is a multilayer, the substrate 200 can include a first substrate 601, an intermediate substrate layer 602, and a second substrate 603. The intermediate substrate layer 602 can be located between the first substrate 601 and the second substrate 603. For example, each of the first substrate 601 and the second substrate 603 can be a polyimide (PI) layer, but the embodiments of the present disclosure are not limited thereto. The intermediate substrate layer 602 can be an inorganic insulating layer, but the embodiments of the present disclosure are not limited thereto. If a charge is charged in the first substrate 601, which is a polyimide layer, the intermediate substrate layer 602 can block the charge from affecting transistors disposed on the second substrate 603 through the second substrate 603, which is a polyimide layer.

In addition, the intermediate substrate layer 602 can block moisture components from penetrating upward through the first substrate 601. For example, the intermediate substrate layer 602 can be formed of a single layer of silicon nitride (SiNx) or silicon oxide (SiOx) or a multilayer thereof, and can be formed of a double layer of silicon dioxide (SiO2) and silicon nitride (SiNx), but is not limited thereto.

The transistor section can include insulating layers 611, 612 and 613 on the substrate 200, a thin film transistor TFT, a storage capacitor Cst, and various electrodes or signal lines.

The thin film transistor TFT can include an active layer ACT, a first electrode Ea, a second electrode Eb, and a third electrode Ec.

The first electrode Ea can be a gate electrode, the second electrode Eb can be a source electrode or a drain electrode, and the third electrode Ec can be a drain electrode or a source electrode. Hereinafter, for convenience of explanation, it is assumed that the first electrode Ea is a first gate electrode EA, the second electrode Eb is a first source electrode Eb, and the third electrode Ec is a first drain electrode Ec. However, the embodiments of the present disclosure are not limited thereto.

The active layer ACT can include a first semiconductor material. For example, the first semiconductor material can include an oxide semiconductor, amorphous silicon, polysilicon, or low-temperature polysilicon (LTPS), but the embodiments of the present disclosure are not limited thereto. The thin film transistor TFT can be implemented as a p-channel transistor or an n-channel transistor, but the embodiments of the present disclosure are not limited thereto.

The types of semiconductor materials of the active layer ACT of the thin film transistor TFT can be as follows.

As an example, the active layer ACT of the thin film transistor TFT can include an oxide semiconductor material. For another example, the active layer ACT of the thin film transistor TFT can include a low-temperature polysilicon semiconductor material. For another example, the active layer ACT of the thin film transistor TFT can include an oxide semiconductor material.

The usage of the transistor within the display area DA can be as follows:

For example, all the transistors within each sub-pixel SP can be implemented as thin film transistors TFT including a low-temperature polysilicon semiconductor material. For another example, all the transistors within each sub-pixel SP can be implemented as thin film transistors TFT including an oxide semiconductor material. For another example, some of all the transistors within each sub-pixel SP can be implemented as thin film transistors TFT including a low-temperature polysilicon semiconductor material, and some can be implemented as thin film transistors TFT including an oxide semiconductor material. For example, each sub-pixel SP can include at least one thin film transistor TFT including a low-temperature polysilicon semiconductor material and at least one thin film transistor TFT including an oxide semiconductor material.

If some of all the transistors in each sub-pixel SP are implemented as thin film transistors TFT including a low-temperature poly-silicon semiconductor material, and the remaining some are implemented as thin film transistors TFT including an oxide semiconductor material, the following examples can be possible.

As an example, in each sub-pixel SP, a driving transistor DT can be implemented as a thin film transistor TFT including a low-temperature poly-silicon semiconductor material, and other transistors (e.g., a scan transistor ST, an emission control transistor, etc.) can be implemented as thin film transistors TFT including an oxide semiconductor material.

As another example, in each sub-pixel SP, the driving transistor DT can be implemented as a thin film transistor TFT including an oxide semiconductor material, and other transistors (e.g., a scan transistor ST, an emission control transistor, etc.) can be implemented as thin film transistors TFT including a low-temperature polysilicon semiconductor material.

In FIG. 6, a thin film transistor TFT connected to a pixel electrode PE of the light emitting device ED can be the driving transistor DT or a transistor different from the driving transistor DT depending on the configuration of the sub-pixel circuit SPC. For example, in FIG. 6, the thin film transistor TFT connected to the pixel electrode PE of the light emitting device ED can be an emission control transistor connected between the driving transistor DT and the light emitting device ED.

The use of the transistors in the non-display area NDA can be as follows.

For example, the active layers of the transistors included in a gate driving circuit 240 of the gate-in-panel (GIP) type can be composed of an oxide semiconductor material. As another example, the active layers of the transistors included in the gate driving circuit 240 of the gate-in-panel (GIP) type can be composed of a low-temperature polysilicon semiconductor material. As another example, among the transistors included in the gate driving circuit 240 of the gate-in-panel (GIP) type, some of the active layers can be composed of a low-temperature polysilicon semiconductor material, and other of the active layers can be composed of an oxide semiconductor material.

A buffer layer 611 can be disposed under the active layer ACT of the thin film transistor TFT.

The storage capacitor Cst can be disposed within various metal layers within the display panel 110. For example, the storage capacitor Cst can include a first capacitor electrode CAPE1 and a second capacitor electrode CAPE2.

The light emitting device section can include a plurality of light emitting devices ED arranged on a planarization layer 620. Each of the plurality of light emitting devices ED can include a pixel electrode PE, an intermediate layer EL, and a common electrode CE.

The encapsulation section can include an encapsulation layer 300 on the plurality of light emitting devices ED. The encapsulation layer 300 can be a single layer or a multilayer, but the embodiments of the present disclosure are not limited thereto.

Hereinafter, the structure or vertical structure of the display panel 110 according to the embodiments of the present disclosure will be described in more detail with reference to FIG. 6.

Referring to FIG. 6, a buffer layer 611 can be disposed on the substrate 200. The buffer layer 611 can be a single layer or a multilayer, but the embodiments of the present disclosure are not limited thereto. If the buffer layer 611 is a multilayer, the buffer layer 611 can include a lower buffer layer and an upper buffer layer.

An active layer ACT of a thin film transistor TFT can be disposed on the buffer layer 611. The active layer ACT can include a channel area where a channel is formed, a source connection area on one side of the channel area, and a drain connection area on the other side of the channel area.

A gate insulating layer 612 can be disposed on the active layer ACT of the thin film transistor TFT. A gate electrode EA of the thin film transistor TFT can be disposed on the gate insulating layer 612. An interlayer insulating layer 613 can be disposed on the gate electrode EA of the thin film transistor TFT. Here, a metal layer on which the gate electrode EA of the thin film transistor TFT is disposed can be referred to as a first gate metal layer.

A source electrode Eb and a drain electrode Ec of the thin film transistor TFT can be respectively connected to the source connection area and the drain connection area of the active layer ACT through the holes of the interlayer insulating layer 613, the gate insulating layer 612, and the buffer layer 611.

The source electrode Eb and the drain electrode Ec of the thin film transistor TFT can include a source-drain metal and can be disposed within the source-drain metal layer.

Referring to FIG. 6, as an example, the storage capacitor Cst can be formed by the first capacitor electrode CAPE1 and the second capacitor electrode CAPE2. In some cases, the storage capacitor Cst can be formed by three or more capacitor electrodes, and can be in the form of two or more capacitors connected in parallel.

Each of the first capacitor electrode CAPE1 and the second capacitor electrode CAPE2 can be disposed on various metal layers disposed within the display panel 110.

For example, the first capacitor electrode CAPE1 can include the same first gate metal as the gate electrode EA of the thin film transistor TFT on the gate insulating layer 612, and can be disposed within the first gate metal layer, but the embodiments of the present disclosure are not limited thereto. For example, the second capacitor electrode CAPE2 can be disposed on the interlayer insulating layer 613.

The planarization layer 620 can be disposed on the thin film transistor TFT and below the light emitting device ED. The planarization layer 620 can be an organic insulating layer including an organic insulating material.

As an example, the planarization layer 620 can be composed of one layer. As another example, the planarization layer 620 can include two layers. The planarization layer 620 can include a first planarization layer 621 and a second planarization layer 622. As another example, the planarization layer 620 can include three or more layers. The embodiments of the present disclosure are not limited thereto.

Referring to FIG. 6, the first planarization layer 621 can be disposed on the source electrode Eb and the drain electrode Ec of the thin film transistor TFT. For example, the first planarization layer 621 can be disposed on the thin film transistor TFT. For example, the first planarization layer 621 can be disposed to cover the entire thin film transistor TFT.

The first planarization layer 621 can be positioned over the entire display area DA.

A connection electrode RE can be disposed on the first planarization layer 621. The connection electrode RE can electrically connect the source electrode Eb of the thin film transistor TFT and the pixel electrode PE.

The connection electrode RE can be disposed within the source-drain metal layer on the first planarization layer 621 and can include a source-drain metal.

The second planarization layer 622 can be disposed on the connection electrode RE.

The first planarization layer 621 and the second planarization layer 622 can be disposed so that a portion corresponding to the transmission area TA is different from a portion corresponding to the emission area EA in order to increase the light transmittance in the transmission area TA. For example, the first planarization layer 621 and the second planarization layer 622 can be disposed thinner or not arranged at least in the area where the transmission area TA of the optical area OA is disposed, compared to the first planarization layer 621 and the second planarization layer 622 arranged in the emission area EA.

Specifically, the first planarization layer 621 can have a thickness thinner in the portion corresponding to the transmission area TA than in the portion corresponding to the emission area EA. In addition, the second planarization layer 622 may not be disposed at least in a portion corresponding to the transmission area TA.

In the transmission area TA, the first planarization layer 621 can be disposed thinly and the second planarization layer 622 can be not disposed, thereby increasing the transmittance.

A non-transmission area NTA can include at least an area where the emission area EA and the second planarization layer 622 are disposed. For example, the second planarization layer 622 can be disposed on the first planarization layer 621 and can be located in the non-transmission area NTA within the optical area OA. The transmission area TA can be an area that does not overlap with the light emitting device ED, and can be an area that does not overlap with the second planarization layer.

The light emitting device section can be disposed on the second planarization layer 622. The light emitting device ED can be formed on the second planarization layer 622. The light emitting device ED can include a pixel electrode PE, an intermediate layer EL, and a common electrode CE. The emission area of the light emitting device ED can be formed in an area where the pixel electrode PE, the intermediate layer EL, and the common electrode CE overlap and contact each other.

The pixel electrode PE can be disposed on the second planarization layer 622. The pixel electrode PE can be electrically connected to the connection electrode RE through a hole of the second planarization layer 622. At least a portion of the pixel electrode PE can overlap with the emission area EA on the second planarization layer 622.

A bank 630 can be disposed on the pixel electrode PE. An opening of the bank 630 can expose a part of the pixel electrode PE to form an emission area. The opening of the bank 630 can overlap with a part of the pixel electrode PE.

For example, the bank 630 can be composed of a material including a black pigment, or an organic material such as a benzocyclobutene resin, a polyimide resin, an acrylic resin, or a photosensitive polymer, but the embodiments of the present disclosure are not limited thereto. If the bank 630 is composed of a material including a black pigment or a black dye, the bank can be a black bank. If the bank 630 is composed of a material including a black pigment or a black dye, the bank can block light from the outside or light reflected from the outside, thereby further increasing the luminance or the brightness of the display device 100. Alternatively, the bank 630 can be composed of a transparent material that does not include a black dye and allows light to pass through.

The intermediate layer EL of the light emitting device ED can be disposed on a portion of the pixel electrode PE and the bank 630. The common electrode CE can be disposed on the intermediate layer EL.

Referring to FIG. 3, the encapsulation section can be disposed on the light emitting device section and can be located on the common electrode CE. The encapsulation section can include an encapsulation layer 300 formed on the common electrode CE.

The encapsulation layer 300 can prevent moisture or oxygen from penetrating into the light emitting device ED. For example, the encapsulation layer 300 can prevent moisture or oxygen from penetrating into an organic material included in the intermediate layer EL of the light emitting device ED. The encapsulation layer 300 can be composed of a single layer or multiple layers, but the embodiments of the present disclosure are not limited thereto.

For example, the encapsulation layer 300 can include a first encapsulation layer 631, a second encapsulation layer 632, and a third encapsulation layer 633, but the embodiments of the present disclosure are not limited thereto. For example, the first encapsulation layer 631 and the third encapsulation layer 633 can include inorganic encapsulation layers, and the second encapsulation layer 632 can include an organic encapsulation layer, but the embodiments of the present disclosure are not limited thereto.

The display panel 110 according to the embodiments of the present disclosure can include a color filter 650 of a built-in type. In this case, the display panel 110 according to the embodiments of the present disclosure can have a black matrix 640 and a color filter 650 disposed on the encapsulation layer 300.

Referring to FIG. 6, a black matrix 640 can be disposed on the encapsulation layer 300 of the display panel 110. The black matrix 640 can be disposed so as to surround the emission area EA without overlapping with the emission area EA. The black matrix 640 can be disposed so as to overlap with the non-transmission area NTA. For example, the black matrix 640 may not overlap with the emission area TA.

The color filter 650 can be disposed in an inner area surrounding the emission area EA so as to overlap with the emission area EA. For example, the color filter 650 can be disposed so as to overlap with the emission area EA and be surrounded by the black matrix 640. Light output from the light emitting device ED can be adjusted to be an electromagnetic wave having a specific wavelength band by passing through the color filter 650.

An overcoat layer 660 can be disposed on the black matrix 640 and the color filter 650. The overcoat layer 660 can be used to level the lower steps, and can be made of an organic material such as photo acryl, polyimide, benzocyclobutene resin, or acrylate resin.

According to the embodiments of the present disclosure, the display panel 110 can have an optical electronic device 11 disposed on the rear surface of the substrate 200 corresponding to the optical area OA, as described in FIG. 1. The optical electronic device 11 can receive light transmitted through the transmission area TA. The optical electronic device 11 can perform a predefined operation using the received light.

Meanwhile, as described above, the optical area OA can have a smaller number of sub-pixels per unit area than the normal area NA by arranging the transmission area TA that does not include the light emitting device ED in order to increase the transmittance, so that the characteristics of the image display related to the luminance in the optical area OA can be lower than the characteristics of the image display in the normal area NA.

In addition, referring to FIG. 6, some of the light emitted from the first light emitting device ED1 of the optical area OA can be totally reflected along the light path shown in FIG. 6 and trapped inside due to total reflection caused by the difference in refractive index between the encapsulation layers 300.

Accordingly, a problem can occur in which the brightness of the display panel 110 output from the optical area OA is reduced. In addition, interference can also occur in the light received by the optical electronic device 11 through the transmission area TA, which can interfere with the normal operation of the optical electronic device 11.

In order to solve this problem, the encapsulation layer 300 can be arranged in a manner described in the following drawings.

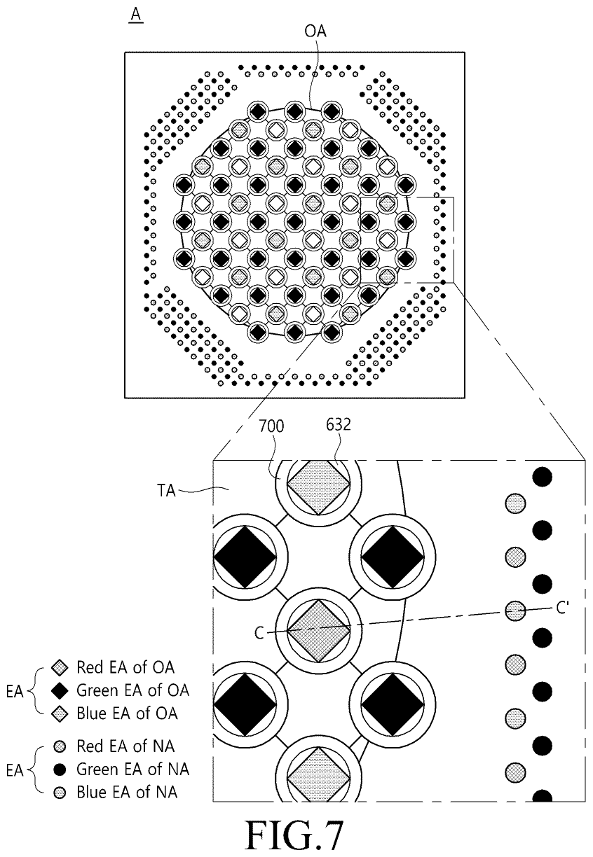

FIG. 7 is a plan view of the area A shown in FIG. 4 according to embodiments of the present disclosure, and an enlarged view of a portion of the plan view of the area A.

Referring to FIG. 7, a dam 700 can be disposed around each of the emission areas EA arranged in the optical area OA. The dam 700 can be disposed in a ring shape to surround the emission areas EA corresponding to each sub-pixel SP. In FIG. 7, it is illustrated that the dam 700 is disposed in a ring shape to surround the emission areas EA in a circular shape, but the embodiments of the present disclosure is not limited thereto. For example, the dam can be disposed to surround the emission areas EA in a square shape to correspond to the shape of each emission area EA.

In addition, the second encapsulation layer 632 can be disposed to overlap with the area surrounded by the dam 700. For example, the second encapsulation layer 632 can be arranged to overlap with the emission areas EA corresponding to each sub-pixel SP in the optical area OA, but can be disposed not to overlap with the transmission area TA.

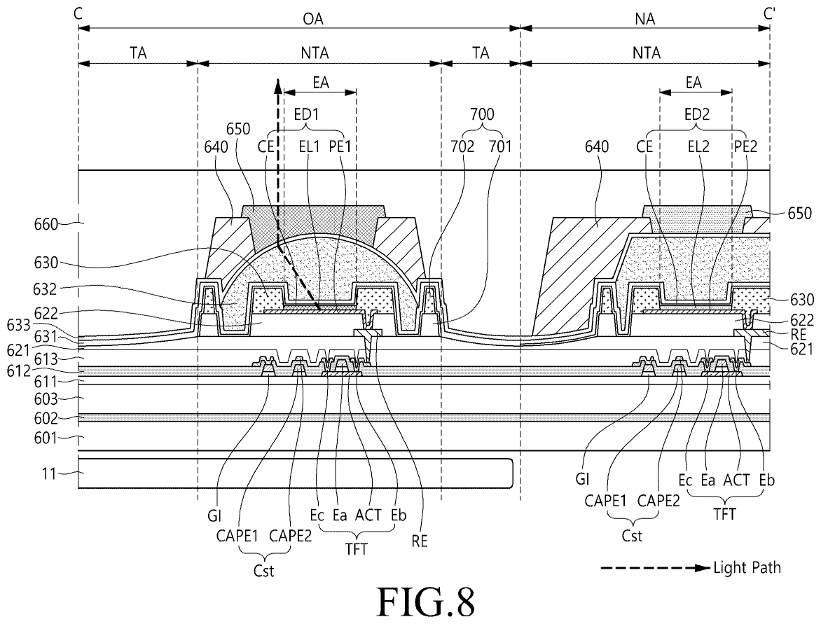

FIG. 8 is a cross-sectional view of the display panel 110 along the C-C′ dotted line shown in FIG. 7.

Referring to FIG. 8, the remaining configurations except for the encapsulation layer 300 can be the same as the configurations described above in FIG. 6. Therefore, a detailed description of the remaining configurations except for the encapsulation layer 300 will be omitted.

The display area DA of the display device 100 can include a normal area NA and an optical area OA capable of transmitting light. The normal area NA can include a plurality of emission areas EA, and the optical area OA can include a plurality of transmission areas TA and a plurality of non-transmission areas NTA. The non-transmission area NTA can include a plurality of emission areas EA.

In the emission areas EA arranged in the normal area NA and the optical area OA, a first pixel electrode PE1 can be disposed to overlap with each of the emission areas EA. A first intermediate layer EL1 can be disposed on the first pixel electrode PE1. A common electrode CE can be disposed on the first intermediate layer EL1.

The first pixel electrode PE1, the first intermediate layer EL1, and the common electrode CE can form one light emitting device ED. The common electrode CE can be disposed over the entire display area DA, but can include an opening corresponding to the transmission area TA of the optical area OA. For example, the common electrode CE can be disposed so as not to overlap with the transmission area TA of the optical area OA.

A bank 630 can be disposed between the pixel electrode PE and the common electrode CE. The bank 630 can have an opening corresponding to the emission area EA, and a pixel electrode PE and an intermediate layer EL can be disposed in the opening of the bank 630.

A dam 700 can be disposed in the optical area OA. The dam 700 can be disposed in the non-transmission area NTA. The dam 700 can be disposed to surround the emission area EA. Referring to FIGS. 7 and 8, the dam 700 can be disposed to surround the emission areas EA corresponding to each sub-pixel SP.

The first pixel electrode PE1 disposed in the optical area OA can be arranged to overlap with the emission area EA inside the dam 700 on the second planarization layer 622.

The dam 700 can be divided into a lower portion 701 and an upper portion 702. The lower portion 701 of the dam 700 can include the same material as the second planarization layer 622. The upper portion 702 of the dam 700 can include the same material as the bank.

The bank 630 can be located in an inner space surrounded by each of the dams 700.

The second planarization layer 622 disposed in the non-transmission area NTA so as not to overlap with the transmission area TA can be located in the inner space surrounded by each of the dams 700. The dam 700 can be laterally spaced from the second planarization layer 622.

A first encapsulation layer 631, which is an inorganic layer, can be arranged on the common electrode CE. The first encapsulation layer 631 can be arranged over the entire display area DA.

A second encapsulation layer 632 can be disposed on a first encapsulation layer 631. In this case, the second encapsulation layer 632 can be located in the inner space surrounded by the ring-shaped dam 700. For example, the second encapsulation layer 632 can be disposed to overlap with the emission area EA but not overlap with the transmission area TA. Accordingly, the second encapsulation layer 632 can be disposed to overlap with the intermediate layer EL.

The second encapsulation layer 632 can be disposed in a dome shape that becomes thicker toward its center. The second encapsulation layer 632 can be disposed to fill the space where the second planarization layer 622 and the dam 700 are laterally spaced apart. For example, the dam 700 has the effect of preventing the second encapsulation layer 632, which is an organic encapsulation layer made of an organic material, from overflowing while having a dome shape.

The light emitted from the first light emitting device ED1 of the optical area OA can have an effect of being emitted to the outside without total reflection when passing through the dome-shaped second encapsulation layer 632. Accordingly, it is possible to provide the effect of increasing brightness in the optical area OA where the dome-shaped second encapsulation layer 632 is disposed.

For example, the light emitting device ED can be disposed in the emission area EA included in the optical area OA, and the second encapsulation layer 632 can be disposed on the entire normal area NA and the emission area EA within the optical area OA. The second encapsulation layer 632 can be disposed separately on each light emitting device ED in the optical area OA and can have a dome shape.

In addition, a dam 700 can be disposed in the optical area OA, and the dam 700 can be disposed to surround a pixel electrode PE included in a light emitting device ED located in the optical area OA. The second encapsulation layer 632 can be located in an inner space surrounded by the dam 700.

Since the second encapsulation layer 632 is disposed in the inner space surrounded by the dam 700, the second encapsulation layer 632 may not overlap with the transmission area TA of the optical area OA. Since the second encapsulation layer 632 does not overlap with the transmission area TA, it is possible to provide an effect of further increasing the transmittance when light received from outside the display device 100 passes through the transmission area TA.

A third encapsulation layer 633, which is an inorganic layer, can be disposed on the second encapsulation layer 632. The third encapsulation layer 633 can be disposed on the entire display area DA.

A black matrix 640 can be disposed on the third encapsulation layer 633. In this case, since the second encapsulation layer 632 includes a dome-shaped curvature that becomes higher toward the center, the length of the black matrix 640 can also be adjusted so that the height of the upper surface is constant along the curvature of the upper surface of the second encapsulation layer 632. For example, the closer the black matrix 640 is placed to the center of the second encapsulation layer 632, the shorter the length, and the closer it is placed to the outer edge of the second encapsulation layer 632, the longer the length. For example, the black matrix 640 can have a shorter length closer to the center of the second encapsulation layer 632, and a longer length closer to the periphery of the second encapsulation layer 632.

Meanwhile, in addition to the embodiment of increasing brightness by arranging the second encapsulation layer 632 disposed in the optical area OA in a dome shape, the brightness can be further improved by forming an inclined surface on the pixel electrode PE.

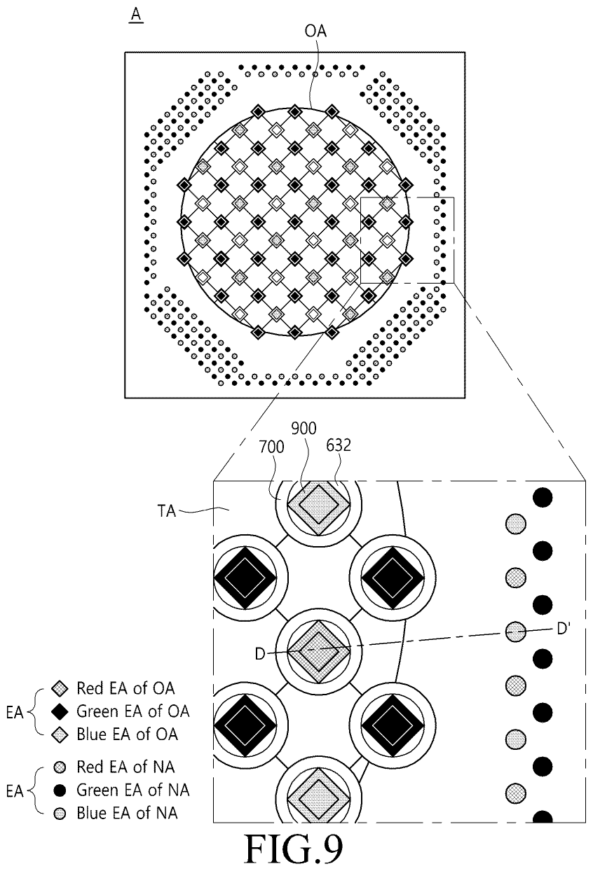

FIG. 9 is a plan view according to embodiments of the present disclosure of the A area shown in FIG. 4, and an enlarged view of a portion of the plan view of the A area.

Referring to FIG. 9, a dam 700 can be disposed around each of the emission areas EA disposed in the optical area OA. The dam 700 can be disposed in a ring shape to surround the emission areas EA corresponding to each sub-pixel SP. For example, it can include the same dam 700 configuration as described above in FIGS. 7 and 8.

In addition, the pixel electrode PE included in the optical area OA can be configured to have an inclined surface 900, so that light having an angle that is emitted laterally from the intermediate layer EL of the light emitting device ED can be reflected to the front of the display panel 110. Accordingly, it is possible to secure the effect of increasing the brightness of the optical area OA.

In addition, since the second encapsulation layer 632 is formed in the shape of a dome, as described in FIGS. 7 and 8, the effect of further increasing the brightness of the optical area OA can be expected on the pixel electrode PE having the inclined surface 900.

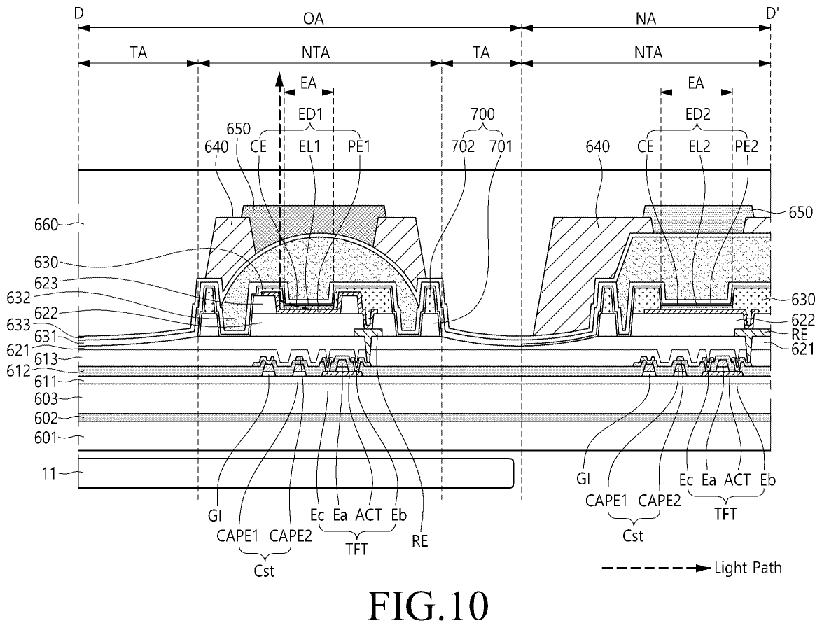

FIG. 10 is a cross-sectional view of the display panel 110 shown along the D-D′ dotted line shown in FIG. 9.

Referring to FIG. 10, the remaining configurations except for the third planarization layer 623 and the pixel electrode PE can be the same as the configurations described in FIGS. 6 and 8. Therefore, a detailed description of the remaining configurations except for the third planarization layer 623 and the pixel electrode PE will be omitted.

A third planarization layer 623 can be disposed between the pixel electrode PE and a second planarization layer 622. The third planarization layer 623 can have an opening corresponding to the emission area EA. The third planarization layer 623 can be located in an inner space surrounded by the dam 700.

The pixel electrode PE can be disposed on the second planarization layer 622 in the opening of the third planarization layer 623. The pixel electrode PE can include an inclined surface 900 extending along a side surface of the third planarization layer 623.

Some of the light generated from the intermediate layer EL can travel in a lateral direction. The light traveling in the lateral direction can be reflected on the inclined surface 900 of the pixel electrode PE formed through the third planarization layer 623 and output to the front surface of the display panel 110. Accordingly, there can provide an effect of increasing the brightness in the emission area EA where the pixel electrode PE including the inclined surface 900 is disposed.

The emission area EA in which the pixel electrode PE including the inclined surface 900 is disposed is illustrated as being arranged in the optical area OA, but can also be arranged in the normal area NA.

Meanwhile, the dam 700 can surround each emission area EA corresponding to the sub-pixel SP, and the second encapsulation layer 632 can also be disposed on each emission area EA corresponding to the sub-pixel SP, but the dam 700 and the second encapsulation layer 632 can also be arranged to correspond to a pixel unit, which is a collection of sub-pixels SP.

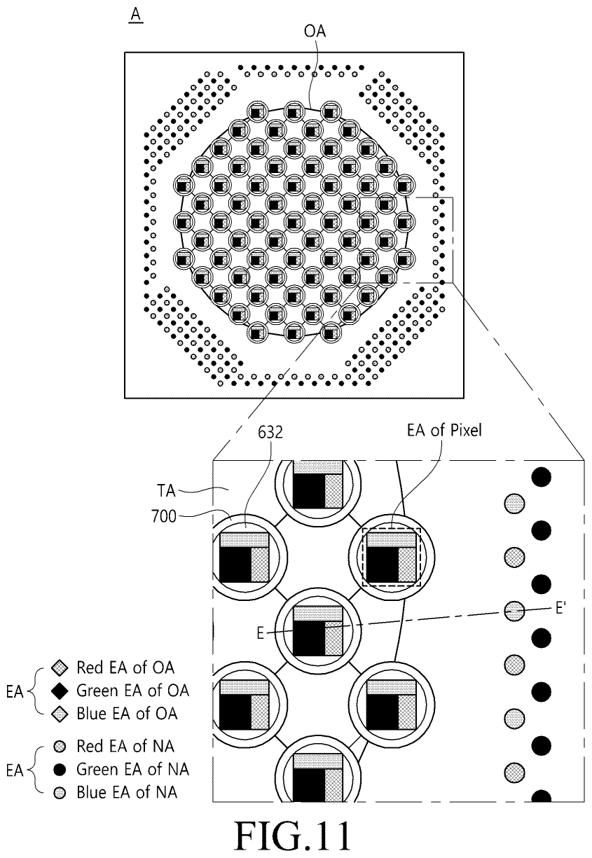

FIG. 11 is a plan view according to embodiments of the present disclosure of the area A shown in FIG. 4, and an enlarged view of a portion of the plan view of the area A.

Referring to FIG. 11, one red emission area EA, one green emission area EA, and one blue emission area EA can form a pixel emission area (i.e., EA of Pixel).

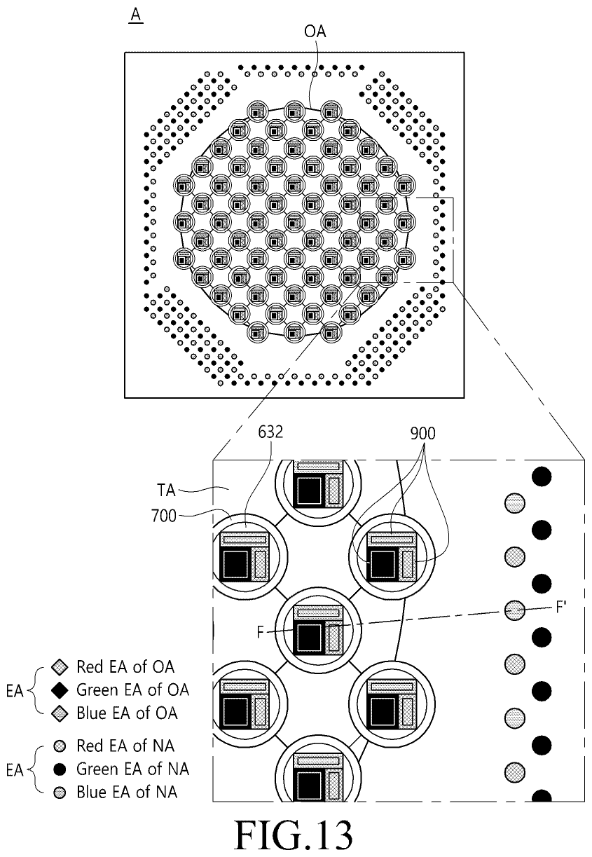

However, this is only an example for explaining the embodiments, and one pixel emission area (i.e., EA of Pixel) can be formed with various emission area EA configurations. For example, one pixel and pixel emission area (i.e., EA of Pixel) can be formed with one sub-pixel SP that outputs red light, two sub-pixels SP that output green light, and one sub-pixel SP that outputs blue light. In the following, for convenience of explanation, it is assumed that one pixel emission area (i.e., EA of Pixel) is formed with one red emission area EA, one green emission area EA, and one blue emission area EA, as shown in FIG. 13.

A dam 700 can be disposed to surround the pixel emission area (i.e., EA of Pixel) corresponding to each pixel. The dam 700 can be disposed in a ring shape to surround the pixel emission area (i.e., EA of Pixel) corresponding to each pixel.

In addition, a second encapsulation layer 632 can be disposed to overlap with the area surrounded by the dam 700. For example, the second encapsulation layer 632 can be disposed to overlap the pixel emission area (i.e., EA of Pixel) corresponding to each pixel in the optical area OA. In addition, the second encapsulation layer 632 can be disposed not to overlap with the transmission area TA.

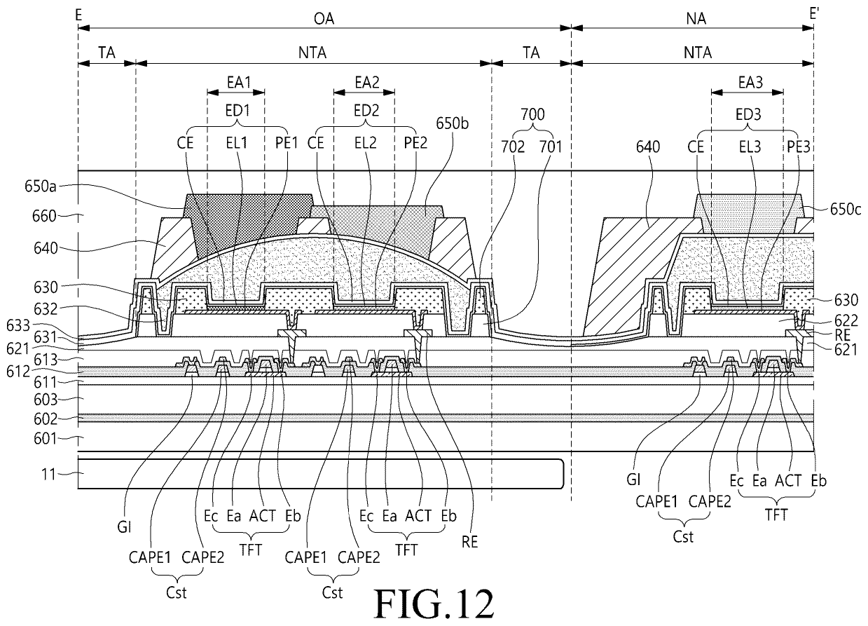

FIG. 12 is a cross-sectional view of the display panel 110 shown along the E-E′ dotted line shown in FIG. 11.

Referring to FIG. 12, detailed descriptions of the same configurations as those described in FIGS. 6, 8, and 10 will be omitted.

Two light emitting devices ED1 and ED2 can be disposed in a non-transmission area NTA where a second planarization layer 622 is disposed. Referring to the planar view of FIG. 11, three light emitting devices are shown to be disposed in one non-transmission area NTA, but FIG. 12 will describe two devices based on the cross-section along the E-E′ dotted line.

For example, a first pixel electrode PE1 and a second pixel electrode PE2 can be disposed on the second planarization layer 622. A first intermediate layer EL1 and a second intermediate layer EL2 can be disposed on each of the first pixel electrode PE1 and the second pixel electrode PE2. A common electrode CE can be disposed on the first intermediate layer EL1 and the second intermediate layer EL2, and the common electrode CE can be disposed integrally over the entire display area DA including the optical area OA, but can include an opening overlapping with the transmission area TA so as not to be arranged in the transmission area TA.

The first intermediate layer EL1 and the second intermediate layer EL2 can overlap with a first emission area EA1 and a second emission area EA2, respectively.

The dam 700 can be disposed to surround the first emission area EA1 corresponding to the first pixel electrode PE1 included in the first light emitting device ED1 and the second emission area EA2 corresponding to the second pixel electrode PE2 included in the second light emitting device ED2. The dam 700 can be disposed in the non-transmission area NTA and can be disposed in a ring shape.

A first encapsulation layer 631, which is an inorganic layer, can be disposed on the common electrode CE. The first encapsulation layer 631 can be disposed over the entire display area DA.

A second encapsulation layer 632 can be disposed on the first encapsulation layer 631. In this case, the second encapsulation layer 632 can be located in an inner space surrounded by the ring-shaped dam 700. For example, the second encapsulation layer 632 can be disposed to overlap with the first emission area EA1 and the second emission area EA2, but not overlap with the transmission area TA. Accordingly, the second encapsulation layer 632 can be disposed to overlap with the first intermediate layer EL1 and the second intermediate layer EL2.

The second encapsulation layer 632 can be disposed in a dome shape that becomes thicker toward the center. Referring to FIG. 12, the dam 700 can be disposed to be spaced apart from the second planarization layer 622 in a lateral direction, and the second encapsulation layer 632 can be disposed to fill the space where the dam 700 and the second planarization layer 622 are spaced apart. For example, the dam 700 can provide an effect of preventing the second encapsulation layer 632, which is an organic encapsulation layer made of an organic material, from overflowing while having a dome shape.

The light emitted from the first light emitting device ED1 and the second light emitting device ED2 of the optical area OA can have an effect of being emitted to the outside without total reflection when passing through the dome-shaped second encapsulation layer 632. Accordingly, there can be an effect of increasing brightness in the optical area OA where the dome-shaped second encapsulation layer 632 is disposed.

Meanwhile, when the dam 700 surrounds at least two pixel electrodes PE corresponding to the first emission area EA1 and the second emission area EA2, each pixel electrode PE can be disposed to have an inclined surface 900 as described above in FIGS. 9 and 10, thereby further enhancing the effect of increasing brightness in the optical area OA.

FIG. 13 is a plan view according to embodiments of the present disclosure of the A area shown in FIG. 4, and an enlarged view of a part of the plan view of the A area.

Referring to FIG. 13, one red emission area EA, one green emission area EA, and one blue emission area EA can form a pixel emission area (i.e., EA of Pixel) corresponding to one pixel.

However, this is only an example for explaining the embodiment, and one pixel emission area (i.e., EA of Pixel) can be formed with various emission area EA configurations. For example, one pixel and pixel emission area (i.e., EA of Pixel) can be formed with one sub-pixel SP that outputs red light, two sub-pixels SP that output green light, and one sub-pixel SP that outputs blue light. Hereinafter, for convenience of explanation, it is assumed that one pixel emission area (i.e., EA of Pixel) is formed with one red emission area EA, one green emission area EA, and one blue emission area EA, as shown in FIG. 13.

The dam 700 can be disposed to surround the pixel emission area (i.e., EA of Pixel) corresponding to each pixel. The dam 700 can be disposed in a ring shape to surround the pixel emission area (i.e., EA of Pixel) corresponding to each pixel.

In addition, referring to FIG. 13, the second encapsulation layer 632 can be disposed to overlap with the area surrounded by the dam 700. For example, the second encapsulation layer 632 can be disposed to overlap with the pixel emission area (i.e., EA of Pixel) corresponding to each pixel in the optical area OA. In addition, the second encapsulation layer 632 can be disposed not to overlap with the transmission area TA.

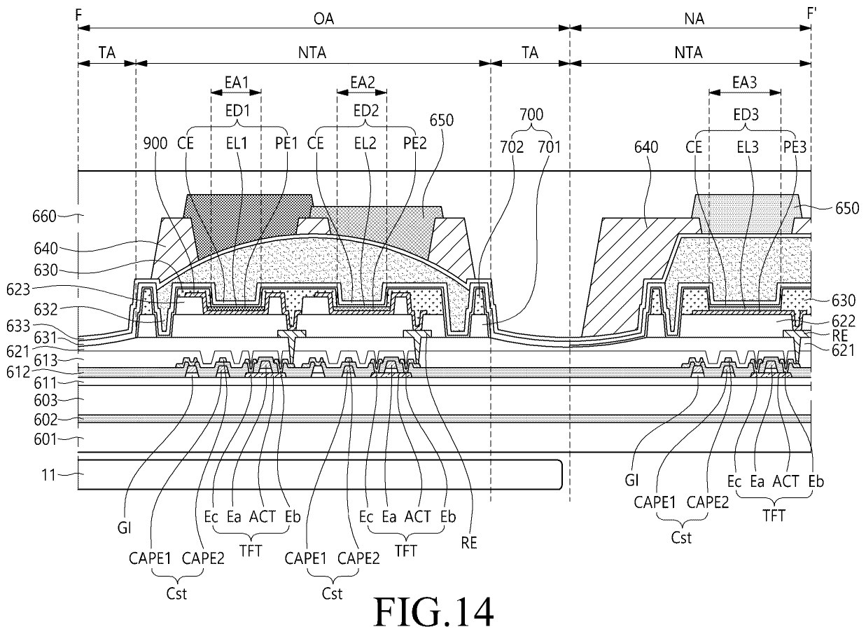

FIG. 14 is a cross-sectional view of the display panel 110 shown along the F-F′ dotted line shown in FIG. 13.

Referring to FIG. 14, a detailed description of the same configurations as those described in FIG. 6, FIG. 8, FIG. 10, and FIG. 12 will be omitted.

As in the embodiment shown in FIG. 12, a third planarization layer 623 can be disposed between the first pixel electrode PE1 and the second pixel electrode and the second planarization layer 622. The third planarization layer 623 can have an opening corresponding to the first emission area EA1 and the second emission area EA2. The third planarization layer 623 can be located in an inner space surrounded by the dam 700.

The first pixel electrode PE1 and the second pixel electrode PE2 can be disposed on the second planarization layer 622 in the opening of the third planarization layer 623. The first pixel electrode PE1 and the second pixel electrode PE2 can include an inclined surface 900 extending along a side surface of the third planarization layer 623.

Some of the light generated from the first intermediate layer EL1 and the second intermediate layer EL2 can travel laterally. The light traveling laterally can be reflected on the inclined surface 900 of the first pixel electrode PE1 and the second pixel electrode PE2 formed through the third planarization layer 623 and output to the front of the display panel 110. Accordingly, there can provide an effect of further increasing the brightness in the emission area EA where the pixel electrode PE including the inclined surface 900 is disposed.

The pixel electrode PE including the inclined surface 900 can be disposed not only in the optical area OA but also in the normal area NA. The third planarization layer 623 can be disposed between a third pixel electrode PE3 and the second planarization layer 622. The third pixel electrode PE3 disposed to overlap with an emission area EA of the normal area NA can include an inclined surface 900 extending along the side of the third planarization layer 623.

Meanwhile, the dam 700 can surround the first emission area EA1 and the second emission area EA2, and the second encapsulation layer 632 can be disposed to overlap with the first emission area EA1 and the second emission area EA2.

The display device according to the embodiments of the present disclosure can be described as follows.

A display device according to embodiments of the present disclosure can include a substrate including a display area with a normal area and an optical area capable of transmitting light, the normal area including a plurality of first emission areas, the optical area including a plurality of transmission areas and a plurality of non-transmission areas, and the plurality of non-transmission areas including a plurality of second emission areas, a plurality of pixel electrodes disposed on the substrate so as to overlap with each of the plurality of first emission areas and the plurality of second emission areas, a plurality of emission layers disposed on each of the plurality of pixel electrodes, a common electrode disposed on the plurality of emission layers, a plurality of dams located in the optical area, and an organic encapsulation layer disposed on the common electrode and located in an inner space surrounded by each of the plurality of dams, wherein each of the plurality of dams surrounds at least one pixel electrode corresponding to at least one second emission area among the plurality of second emission areas.

The display device according to embodiments of the present disclosure can further include a first inorganic encapsulation layer disposed between the common electrode and the organic encapsulation layer, and a second inorganic encapsulation layer disposed on the organic encapsulation layer. The first inorganic encapsulation layer and the second inorganic encapsulation layer can be disposed over the entire display area.

Each of the plurality of dams can have a ring shape, and the organic encapsulation layer can have a dome shape that becomes thicker toward the center.

The organic encapsulation layer can be disposed in at least one second emission area among the plurality of second emission areas and can overlap with at least one emission layer.

An optical electronic device can be disposed on a rear surface of the substrate of the optical area, and the optical electronic device can perform a predefined operation using light transmitted through the transmission area.

Each of the plurality of dams can surround at least two pixel electrodes corresponding to at least two second emission areas among the plurality of second emission areas.

The display device according to embodiments of the present disclosure can further include a first planarization layer disposed between the substrate and the plurality of pixel electrodes, and located over the entire display area, a second planarization layer disposed on the first planarization layer, and located in the non-transmission area within the optical area, and a bank disposed on the pixel electrodes, and having an opening. The bank can be located in the inner space surrounded by each of the plurality of dams, and the pixel electrode can be located in the opening of the bank.

The second planarization layer can be located in the inner space surrounded by each of the plurality of dams.

Each of the plurality of dams can be laterally spaced from the second planarization layer, and a space in which each of the plurality of dams is laterally spaced from the second planarization layer can be filled with the organic encapsulation layer.

Each of the plurality of dams can include a lower portion and an upper portion. The lower portion can include the same material as the second planarization layer, and the upper portion can include the same material as the bank.

The display device according to embodiments of the present disclosure can further include a third planarization layer disposed on the second planarization layer and having an opening. The third planarization layer can be located in the inner space surrounded by each of the plurality of dams. The pixel electrode can be disposed on the second planarization layer in the opening of the third planarization layer, and can include an inclined surface extending along a side surface of the third planarization layer.

The pixel electrode can overlap with at least a portion of the second emission area within the dam on the second planarization layer.

The display device according to embodiments of the present disclosure can further include a third planarization layer disposed on the second planarization layer and having an opening. The second planarization layer can be disposed so that at least a portion of the second planarization layer overlaps with the first emission area within the normal area, and the third planarization layer can be disposed so that the opening corresponds to the first emission area. The pixel electrode can be disposed on the second planarization layer in the opening of the third planarization layer, and can include an inclined surface extending along a side surface of the third planarization layer.

The pixel electrode can overlap with at least a portion of the first emission area on the second planarization layer.

The display device according to embodiments of the present disclosure can further include a black matrix that does not overlap with the transmission area of the optical area and is disposed on the organic encapsulation layer so as to surround the first emission area and the second emission area without overlapping with the first emission area and the second emission area.

The black matrix can be disposed so that the black matrix has a shorter length closer to the center of the organic encapsulation layer, and a longer length closer to the periphery of the organic encapsulation layer.

The display device according to embodiments of the present disclosure can further include a color filter disposed on the organic encapsulation layer. The color filter can be disposed to overlap with the first emission area and the second emission area, and to be surrounded by the black matrix.

The display device according to embodiments of the present disclosure can further include an overcoat layer disposed to correspond to the entire display area including the normal area and the optical area on the organic encapsulation layer.

A display device according to embodiments of the present disclosure can include a substrate including a display area with a normal area and an optical area capable of transmitting light, the normal area including a plurality of first emission areas, and the optical area including a plurality of transmission areas and a plurality of second emission areas, a plurality of first light emitting devices located in each of the plurality of first emission areas, a plurality of second light emitting devices located in each of the plurality of second emission areas, and an organic encapsulation layer disposed throughout the normal area and disposed in the plurality of second emission areas within the optical area. The organic encapsulation layer can be separately disposed on each of at least one of the plurality of second light emitting devices, and can have a dome shape.

The display device according to embodiments of the present disclosure can further include a plurality of dams located in the optical area. Each of the plurality of dams can surround at least one pixel electrode among a plurality of pixel electrodes included in the plurality of second light emitting devices, and the organic encapsulation layer can be located in an inner space surrounded by each of the plurality of dams.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present invention. The above description and the accompanying drawings provide an example of the technical idea of the present invention for illustrative purposes only. For example, the disclosed embodiments are intended to illustrate the scope of the technical idea of the present invention.

What is claimed is:

1. A display device comprising:
a substrate including a display area having a normal area and an optical area capable of transmitting light, the normal area including a plurality of first emission areas, the optical area including a plurality of transmission areas and a plurality of non-transmission areas, and the plurality of non-transmission areas including a plurality of second emission areas;
a plurality of pixel electrodes disposed on the substrate so as to overlap with the plurality of first emission areas and the plurality of second emission areas;
a plurality of emission layers disposed on the plurality of pixel electrodes;
a common electrode disposed on the plurality of emission layers;
a plurality of dams located in the optical area; and
an organic encapsulation layer disposed on the common electrode and located in an inner space surrounded by each of the plurality of dams,
wherein each of the plurality of dams surrounds at least one pixel electrode corresponding to at least one second emission area among the plurality of second emission areas.

2. The display device of claim 1, further comprising:
a first inorganic encapsulation layer disposed between the common electrode and the organic encapsulation layer; and
a second inorganic encapsulation layer disposed on the organic encapsulation layer,
wherein the first inorganic encapsulation layer and the second inorganic encapsulation layer are disposed over the entire display area.

3. The display device of claim 1, wherein each of the plurality of dams has a ring shape,
wherein the organic encapsulation layer has a dome shape that becomes thicker toward a center of the organic encapsulation layer.

4. The display device of claim 1, wherein the organic encapsulation layer is disposed in at least one second emission area among the plurality of second emission areas and overlaps with at least one emission layer.

5. The display device of claim 1, further comprising an optical electronic device disposed on a surface of the substrate in the optical area,
wherein the optical electronic device performs at least one predefined operation using light transmitted through at least one of the plurality of transmission areas.

6. The display device of claim 1, wherein each of the plurality of dams surrounds at least two pixel electrodes corresponding to at least two second emission areas among the plurality of second emission areas.

7. The display device of claim 1, further comprising:
a first planarization layer disposed between the substrate and the plurality of pixel electrodes, and located over the entire display area;
a second planarization layer disposed on the first planarization layer, and located in one of the plurality of non-transmission areas within the optical area; and
a bank disposed on the plurality of pixel electrodes, and having an opening,
wherein the bank is located in the inner space surrounded by each of the plurality of dams, and
wherein one of the plurality of pixel electrodes is located in the opening of the bank.

8. The display device of claim 7, wherein the second planarization layer is located in the inner space surrounded by each of the plurality of dams.

9. The display device of claim 8, wherein each of the plurality of dams is laterally spaced from the second planarization layer, and
wherein a space in which each of the plurality of dams is laterally spaced from the second planarization layer is filled with the organic encapsulation layer.

10. The display device of claim 7, wherein each of the plurality of dams includes a lower portion and an upper portion,
wherein the lower portion includes a same material as the second planarization layer, and
wherein the upper portion includes a same material as the bank.

11. The display device of claim 7, further comprising a third planarization layer disposed on the second planarization layer and having an opening,
wherein the third planarization layer is located in the inner space surrounded by each of the plurality of dams,
wherein the one of the plurality of pixel electrodes is disposed on the second planarization layer in the opening of the third planarization layer, and includes an inclined surface extending along a side surface of the third planarization layer.

12. The display device of claim 7, wherein the one of the plurality of pixel electrodes overlaps with at least a portion of one of the plurality of second emission areas within one of the plurality of dams on the second planarization layer.

13. The display device of claim 7, further comprising a third planarization layer disposed on the second planarization layer and having an opening,
wherein the second planarization layer is disposed so that at least a portion of the second planarization layer overlaps with one of the plurality of first emission areas within the normal area,
wherein the third planarization layer is disposed so that the opening corresponds to the one of the plurality of first emission areas, and
wherein the one of the plurality of pixel electrodes is disposed on the second planarization layer in the opening of the third planarization layer, and includes an inclined surface extending along a side surface of the third planarization layer.

14. The display device of claim 7, wherein the one of the plurality of pixel electrodes overlaps with at least a portion of one of the plurality of first emission areas on the second planarization layer.

15. The display device of claim 1, further comprising a black matrix configured to not overlap with one of the plurality of transmission areas of the optical area,
wherein the black matrix is disposed on the organic encapsulation layer so as to surround one of the plurality of first emission areas and one of the plurality of second emission areas without overlapping with the one of the plurality of first emission areas and the one of the plurality of second emission areas.

16. The display device of claim 15, wherein the black matrix is disposed so that the black matrix has a shorter length closer to a center of the organic encapsulation layer, and a longer length closer to a periphery of the organic encapsulation layer.

17. The display device of claim 15, further comprising:
a color filter disposed on the organic encapsulation layer,
wherein the color filter is disposed to overlap with the one of the plurality of first emission areas and the one of the plurality of second emission areas, and to be surrounded by the black matrix.

18. The display device of claim 1, further comprising an overcoat layer disposed to correspond to the entire display area including the normal area and the optical area on the organic encapsulation layer.

19. A display device comprising:
a substrate including a display area having a normal area and an optical area capable of transmitting light, the normal area including a plurality of first emission areas, and the optical area including a plurality of transmission areas and a plurality of second emission areas;
a plurality of first light emitting devices located in each of the plurality of first emission areas;
a plurality of second light emitting devices located in each of the plurality of second emission areas; and
an organic encapsulation layer disposed throughout the normal area and disposed in the plurality of second emission areas within the optical area,
wherein the organic encapsulation layer is separately disposed on each of at least one of the plurality of second light emitting devices, and has a dome shape.

20. The display device of claim 19, further comprising a plurality of dams located in the optical area,
wherein each of the plurality of dams surrounds at least one pixel electrode among a plurality of pixel electrodes included in the plurality of second light emitting devices, and
wherein the organic encapsulation layer is located in an inner space surrounded by each of the plurality of dams.
